(19) United States
(12) Patent Application Publication
(10) Pub. No.: US 2005/0051297 A1
(43) Pub. Date: Mar. 10, 2005

(54) Heat sink

(76) Inventor: Jui-Chen Kuo, Banchiau City (TW)

Correspondence Address: Tai Yuan Exploitation Co., Ltd., P.O. Box No. 6-57, Junghe, Taipei 235, TW

(21) Appl. No.: 10/655,066

(22) Filed: Sep. 5, 2003

(51) Int. Cl. H05K 7/20

(52) U.S. Cl. 165/80.3; 165/185; 361/704

(57) ABSTRACT

An improved heat sink including a plurality of radiating fins constructed therefrom. Two opposite edges of the radiating fins are respectively folded upwards at right angles to the face of the radiating fins. Air vents are defined at applicable distances on the folded edges thereof. On another face of the radiating fins, and distanced relative to the aforementioned air vents on the folded edges, are attached a plurality of protruding pieces affixed at right angles to the face of the radiating fins. A convex protrusion is additionally configured on each of the protruding edges. The convex protrusions reciprocally engage with the air vents of the folded edges, and a string of radiating fins reciprocally engage to form a heat sink in its entirety thereof.

### BACKGROUND OF INVENTION

(a) Field of Inventions

The present invention relates to a heat sink, and more particularly to an improved heat sink structure that constitutes ease of shaping, and provides a large heat dissipating area, unhindered heat dissipating channels, as well as being light in weight. Overall, the present invention is an extremely cost-effective heat sink for the manufacturer.

(b) Description of the Invention

In pace with the ever-increasing processing speed of the central processing unit (CPU) of a computer, correspondingly, the importance of the heat dissipating efficiency of the CPU is increasingly becoming more apparent. A heat sink 10′ of a CPU 20′ in a traditional computer (see FIG. 5) is typically extruded from aluminum or die-cast. The heat sink 10′ is adhered to the CPU 20′, and fastened down with a fastening bracket 30′, a bolt 40′ bolts down a fan 50′ thereon. This is the general method adopted by a typical manufacturer today. The thinner the radiating fins 11′ become, the more in plurality the radiating fins are, and the more narrower the pitch between the radiating fins can be achieved. As a consequence, the heat dissipating area is increased enormously, and the speed of the heat dissipation and heat dissipation efficiency are particularly enhanced. However, because of the limitations in the manufacturing process, the density of the radiating fins 11′ (i.e. The pitch between the radiating fins 11′), as well as the range of thickness of the radiating fins 11′, it is not possible to achieve such results. Furthermore, by requiring to affix the fan 50′ on top of the heat sink 10′, the heat sink 10′ must be drilled with a hole in order to bolt down the fan 50′ thereon. Because of the extreme thickness of the heat sink 10′; it is very difficult for the business providing drilling services to accomplish this drilling. Moreover, because of the extreme thickness of the heat sink 10′, the heat sink 10′ itself will accumulate a substantial amount of heat, which it is unable to dissipate. After long usage, damage is caused to either the CPU 20′ or the entire computer itself.

In light of the shortcomings of conventional methods as detailed in the aforementioned, the inventor of the present invention decided to design an improved heat sink. Realizing years of professional knowledge, and after a multitude of designs and conferment, as well as innumerable trial samples and improvements, the improved heat sink as detailed in the 2( ) present invention was conceived. In particular, the improved heat sink of the present invention is easy to shape, provides a large heat dissipating area, and unhindered heat dissipating channels.

### SUMMARY OF THE INVENTION

The primary objective of the present invention is to provide an improved heat sink comprising radiating fins formed from metal material that is easy to shape.

It is another objective of the present invention to provide an improved heat sink having a large heat dissipating area and high heat dissipation efficiency.

It is a further objective of the present invention to provide an improved heat sink comprising radiating fins that are both thin and light in weight, achieving a light weight for the entire heat sink when fabricated therefrom.

To enable a further understanding of the said objectives and the technological methods of the invention herein, the brief description of the drawings below is followed by the detailed description of the preferred embodiments.

### BRIEF DESCRIPTION OF THE DRAWINGS

FIG. 1 shows an elevational view of the radiating fins according to the present invention.

FIG. 2 shows a cross-sectional view of the radiating fins according to the present invention.

FIG. 3 shows an assembled elevational view of the heat sink according to the present invention.

FIG. 4 shows an elevational view of another embodiment according to the present invention.

FIG. 5 shows an exploded elevational view of a prior art heat sink.

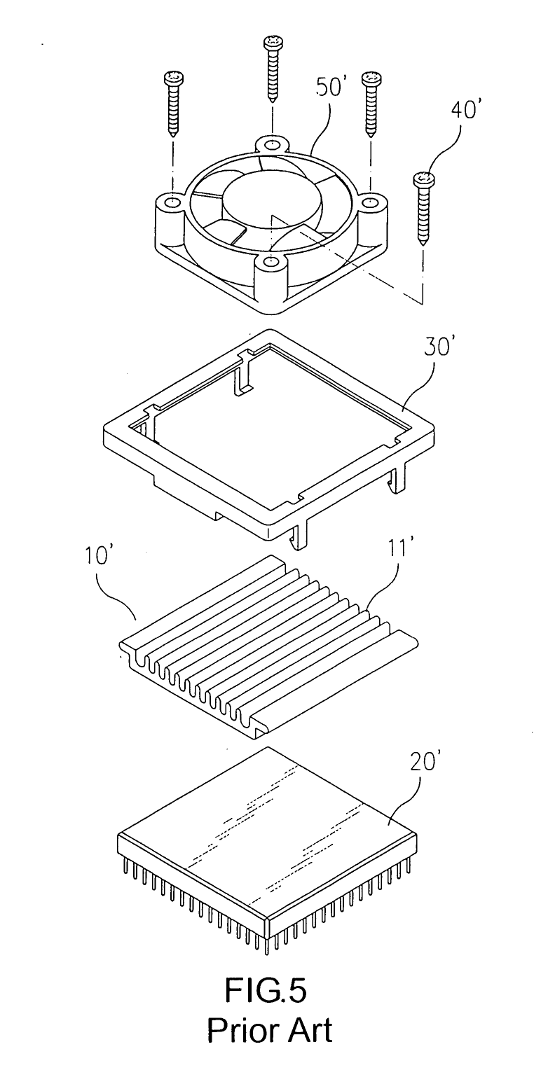

### DESCRIPTION OF THE PREFERRED EMBODIMENTS

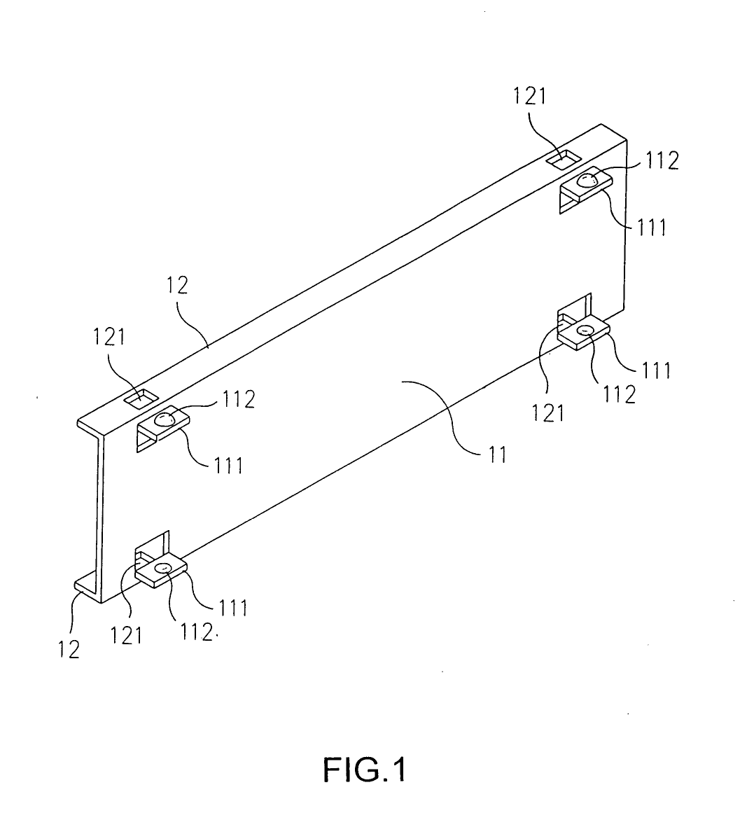

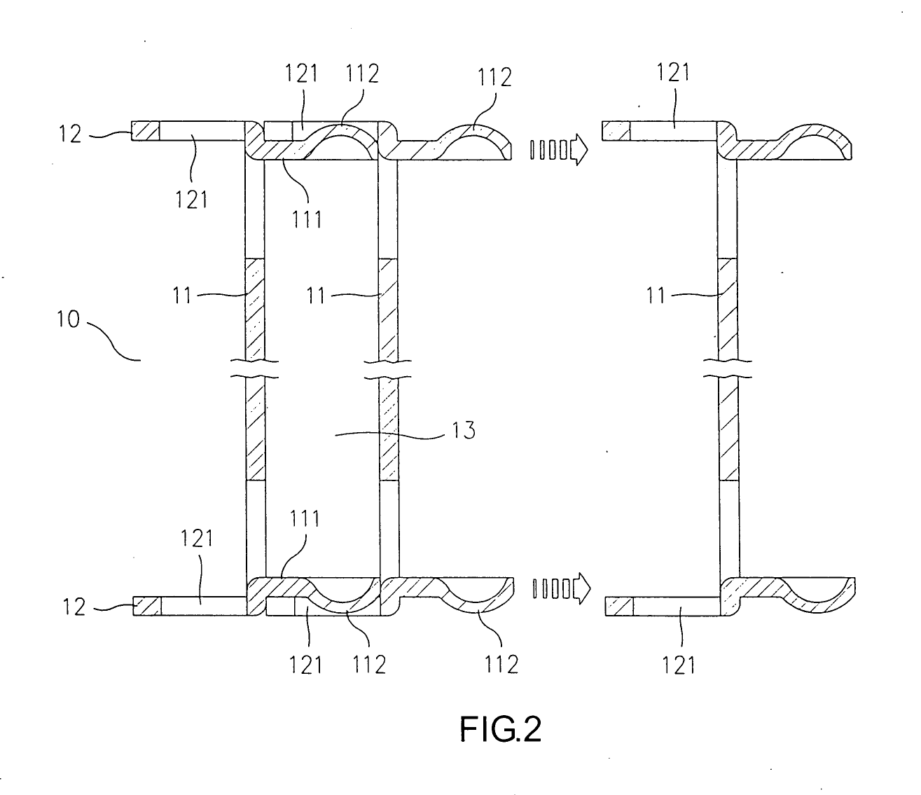

Referring to FIGS. 1, 2, and 3, the drawings depicted therein are chosen to delineate the preferred embodiments according to the present invention, these are merely illustrative and do not limit the principles of the present invention as detailed in the present application.

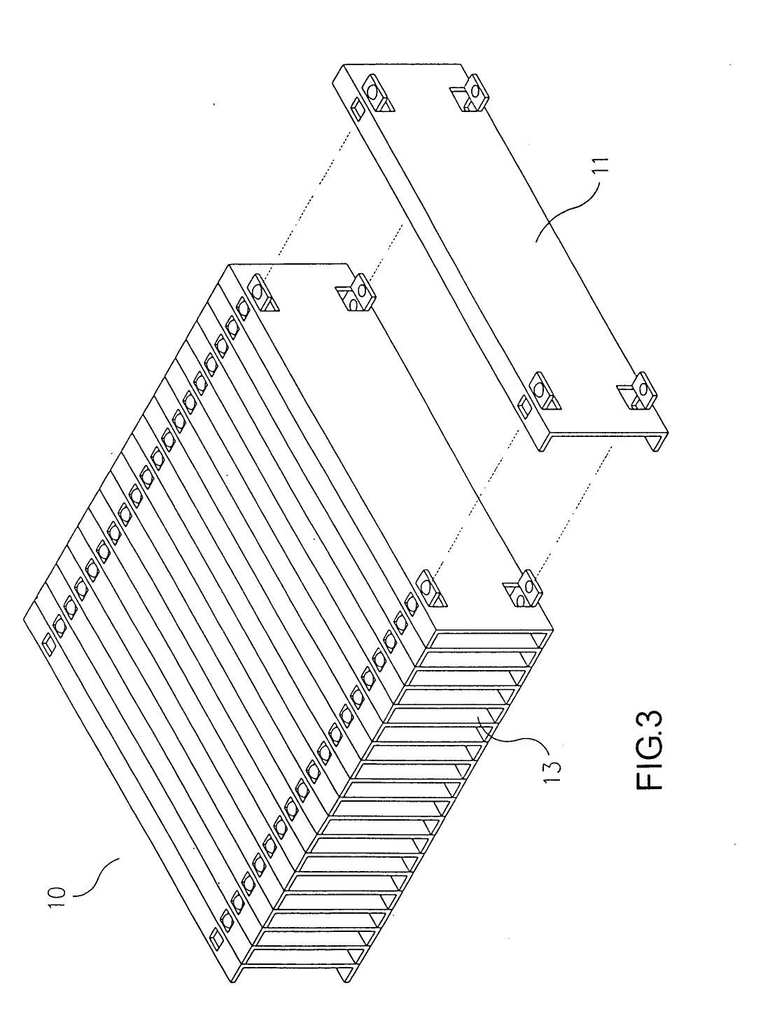

The present invention provides an improved heat sink 10 comprising a plurality of radiating fins 11, the heat sink 10 being constructed therefrom. The radiating fins 11 are formed from an improved heat-conducting metal material and shaped by stamping therefrom. Opposite edges of the radiating fins 11 are folded upwards at right angles forming a folded edge 12 thereof, and air vents 121 are defined at applicable distances on the folded edges 12. As depicted in the drawings, each end of the folded edges 12 are defined with an air vent 121, both upper and lower folded edges 12 respectively being defined with air vents 121 at each end thereof, thus each radiating fin 11 is defined with four air vents in total. On another face of the radiating fins 11, and distanced relative to the aforementioned air vents 121 defined on the folded edges are attached a plurality of protruding pieces 111 affixed at right angles to a side of the radiating fins 11. A convex protrusion 112 is additionally configured on each of the protruding pieces 111. The convex protrusion 112 is designed to be depressable as required on engaging with the air vents 121. The aforementioned convex protrusions 112 of the protruding pieces 111 and air vents 121 of the folded edges 12 are made to reciprocally engage, thereby securing a fastening upon coupling thereof. In this way, one radiating fin after another mutually engage forming a connected row of radiating fins (see FIG. 3). The heat sink 10 is thus fabricated in its entirety thereof. The highly concentrated heat dissipating channels 13 so formed from the heat sink 11 thereby permits rapid heat dissipation therethrough.

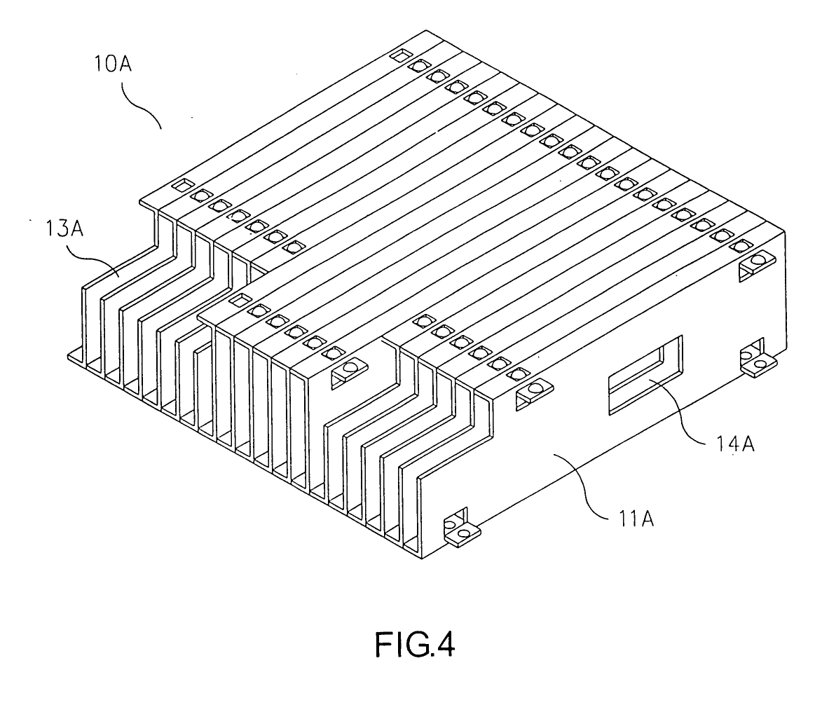

Referring to FIGS. 3 and 4, a heat sink 10 is fabricated from a plurality of radiating fins 11. Because the radiating fins 11 are shaped by stamping, the size of the radiating fins 11 is easily controlled. Even for a heat sink 10A fabricated from irregular shaped radiating fins, all that is required is for radiating fins 11A of different dimensions be coupled together one by one thereby fabricating the heat sink in its entirety. This method of fabricating a heat sink is extremely convenient. A through hole 14A can be further defined on the radiating fins 11A thereof, allowing the through hole 14A and heat dissipating channel 13 to form a cross-thoroughfare for the entire heat sink 10A, thereby accelerating heat dissipation.

From the above detailed explanation of the arts pertaining to the present invention, it can be understood that the primary objective according to the present invention can be attained, and complies with the conditions for applying for a patent herewith. It is of course to be understood that the embodiments described herein is merely illustrative of the principles of the invention and that a wide variety of modifications thereto may be effected by persons skilled in the art without departing from the spirit and scope of the invention as set forth in the following claims.

1. A heat sink comprising a plurality of radiating fins constructed therefrom; two opposite edges of the radiating fins are respectively folded upwards at right angles to a face of the radiating fins forming folded edges; air vents are defined at applicable distances on the folded edges thereof; on another face of the radiating fins, and distanced relative to the aforementioned air vents on the folded edges, are attached a plurality of protruding pieces affixed at right angles to the face of the radiating fins; a convex protrusion is additionally configured on each of the protruding pieces; the aforementioned convex protrusions on each of the protruding edges reciprocally engage with the air vents of the folded edges, and a row of radiating fins in likewise fashion reciprocally engage to form a thoroughfare between the radiating fins.

2. The heat sink according to claim 1, wherein the radiating fins are formed from thin sheets of improved heat-conducting metal material.

3. The heat sink according to claim 1, wherein the convex protrusions on the protruding pieces are not confined to a spherical cambered surface.

4. The heat sink according to claim 1, wherein as depicted in the drawings, each end of the folded edges are defined with an air vent, both upper and lower folded edges respectively being defined with the air vents at each end thereof, thus each radiating fin is defined with four air vents in total.

5. The heat sink according to claim 1, wherein through holes defined on the radiating fins and channels formed from the radiating fins mutually form a thoroughfare, acting as an additional air vent thereof.
